(19) United States
(12) Patent Application Publication
(10) Pub. No.: US 2014/0087498 A1
(43) Pub. Date: Mar. 27, 2014

(54) METHOD OF MANUFACTURING LIGHT-EMITTING DEVICE

(71) Applicant: Toyoda Gosei Co., Ltd., Kiyosu-shi (JP)

(72) Inventors: Takashi TERAYAMA, Kiyosu-shi (JP); Akira Kojima, Kiyosu-shi (JP); Toshimasa Hayashi, Kiyosu-shi (JP); Seiji Yamaguchi, Kiyosu-shi (JP); Hiroyuki Tajima, Kiyosu-shi (JP); Shota Shimonishi, Kiyosu-shi (JP); Yukihiro Demukai, Kiyosu-shi (JP)

(73) Assignee: Toyoda Gosei Co., Ltd., Kiyosu-shi (JP)

(21) Appl. No.: 14/032,083

(22) Filed: Sep. 19, 2013

(30) Foreign Application Priority Data
Sep. 25, 2012 (JP) 2012-210571
Jul. 12, 2013 (JP) 2013-146729

(51) Int. Cl. H01L 33/48

(52) U.S. Cl. CPC H01L 33/48
USPC 438/26

(57) ABSTRACT

A method of manufacturing a light-emitting device includes mounting an LED chip on a bottom surface of a recessed portion of a case, and after mounting the LED chip, forming a highly-reflective sidewall so as to be in contact with side surfaces and the bottom surface of the recessed portion and to be spaced from the LED chip. The highly-reflective sidewall includes a higher light reflectance than the side surfaces of the recessed position of the case and an outwardly convex surface as a surface exposed in the recessed portion.

The present application is based on Japanese patent application Nos.2012-210571 and 2013-146729 filed on Sep. 25, 2012 and Jul. 12, 2013, respectively, the entire contents of which are incorporated herein by reference.

### BACKGROUND OF THE INVENTION

1. Field Of The Invention

The invention relates to a method of manufacturing a light-emitting device.

2. Description Of The Related Art

A conventional light-emitting device is known in which an LED chip is mounted in a case and inner side surfaces of a recessed portion of the case is covered with a coating member formed of a highly-reflective resin so as to efficiently extract light emitted from the LED chip (see, e.g., JP-A-2005-136378).

In the light-emitting device disclosed in JP-A-2005-136378, a resin case has a two-stage structure or a dam shape on the side portion thereof or a lead electrode has a wall portion in a region around an LED chip-mounting region in order to prevent a decrease in light output which is caused because the coating member applied to the side surfaces of the recessed portion of the case flows and comes into contact with the LED chip.

Meanwhile, another known conventional light-emitting device is an LED device having a resin case in which a black resin is used for the outside and a white resin is used for the inside (see, e.g., JP-A-2006-130714).

In addition, yet another known conventional light-emitting device is an LED device having a resin case in which a black resin is used for the outside, a white resin is used for the inside and an edge at a boundary between the outside and the inside is covered with a covering member (see, e.g., JP-A-2010-206039).

### SUMMARY OF THE INVENTION

The light-emitting device disclosed in JP-A-2005-136378, JP-A-2006-130714 and JP-A-2010-206039 needs to be equipped with the resin case or lead electrode having the special shape. Therefore, a special mold, etc., is required in manufacturing the resin case or lead electrode. This may cause an increase in manufacturing cost.

It is an object of the invention to provide a method of manufacturing a light-emitting device that allows a light-emitting device with high light extraction efficiency to be manufactured at low cost.

(1) According to one embodiment of the invention, a method of manufacturing a light-emitting device comprises:

mounting an LED chip on a bottom surface of a recessed portion of a case; and

after mounting the LED chip, forming a highly-reflective sidewall so as to be in contact with side surfaces and the bottom surface of the recessed portion and to be spaced from the LED chip,

wherein the highly-reflective sidewall comprises a higher light reflectance than the side surfaces of the recessed position of the case and an outwardly convex surface as a surface exposed in the recessed portion.

(2) According to another embodiment of the invention, a method of manufacturing a light-emitting device comprises:

forming a highly-reflective sidewall on a surface of a core plate of an injection mold;

forming a case including a resin case that is formed by injecting a resin into a space between the core plate having the highly-reflective sidewall formed thereon and a cavity plate of the injection mold; and

mounting an LED chip on a bottom surface of a recessed portion of the case,

wherein the highly-reflective sidewall is transferred from the core plate to the resin case so as to be provided on side surfaces of the recessed portion of the case.

In the above embodiment (1) or (2) of the invention, the following modifications and changes can be made.

(i) A height of the highly-reflective sidewall is smaller than that of the case.

(ii) The bottom surface of the recessed portion is flat.

(iii) The side surfaces of the recessed portion comprise two first side surfaces and two second side surfaces respectively facing each other with the LED chip interposed therebetween,

wherein a distance between the first side surface and the LED chip is smaller than that between the second side surface and the LED chip, and

wherein the highly-reflective sidewall is formed in a region other than between the first side surface and the LED chip.

(iv) A power-supply wire is connected to the LED chip,

wherein the side surfaces of the recessed portion comprise two first side surfaces and two second side surfaces respectively facing each other with the LED chip interposed therebetween,

wherein a distance between the second side surface and the wire is smaller than that between the first side surface and the wire, and wherein the highly-reflective sidewall is formed in a region other than between the second side surface and the LED chip.

(v) The highly-reflective sidewall is molded outside the case and is then placed so as to be in contact with the side surfaces and the bottom surface of the recessed portion and to be spaced from the LED chip.

(vi) The case is formed reusing a thermoplastic resin that is collected after molding other molded parts.

Effects of the invention

According to one embodiment of the invention, a method of manufacturing a light-emitting device can be provided that allows a light-emitting device with high light extraction efficiency to be manufactured at low cost.

### BRIEF DESCRIPTION OF THE DRAWINGS

Next, the present invention will be explained in more detail in conjunction with appended drawings, wherein:

FIG. 1 is a top view showing a light-emitting device in a first embodiment;

FIGS. 2A and 2B are vertical cross-sectional views showing the light-emitting devices in the first embodiment;

FIGS. 3A to 3C are vertical cross-sectional views showing a manufacturing process of the light-emitting device in the first embodiment;

FIGS. 4A and 4B are top views showing light-emitting devices in a second embodiment;

FIG. 5 is a vertical cross-sectional view showing a light-emitting device in a third embodiment; FIGS. 6A to 6D are vertical cross-sectional views showing a manufacturing process of the light-emitting device in the third embodiment;

FIGS. 7E and 7F are vertical cross-sectional views showing a manufacturing process of the light-emitting device in the third embodiment;

FIGS. 8A to 8D are vertical cross-sectional views showing a manufacturing process of the light-emitting device in the third embodiment;

FIGS. 9E and 9F are vertical cross-sectional views showing a manufacturing process of the light-emitting device in the third embodiment; and

FIGS. 10A and 10B are vertical cross-sectional views showing a modification of a case in the third embodiment.

### DESCRIPTION OF THE PREFERRED EMBODIMENTS

### First embodiment

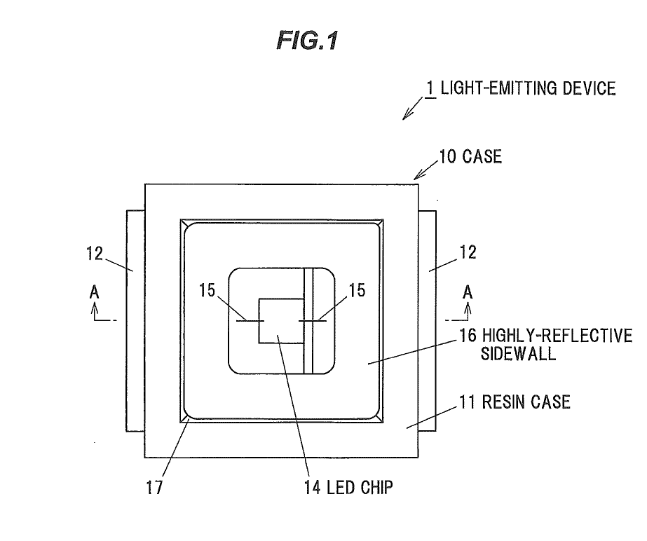

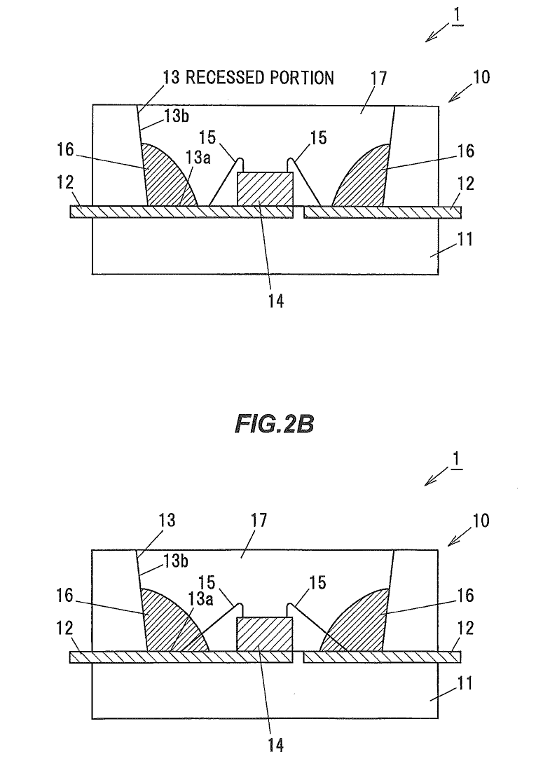

FIG. 1 is a top view showing a light-emitting device in the first embodiment. FIG. 2A is a vertical cross-sectional view showing the light-emitting device taken on line A-A of FIG. 1. A light-emitting device 1 has a case 10 having a recessed portion 13, an LED chip 14 mounted on a bottom surface 13a of the recessed portion 13, a highly-reflective sidewall 16 placed so as to be in contact with side surfaces 13b and the bottom surface 13a of the recessed portion 13 and to be spaced from the LED chip 14, and a sealing member 17 potted in the recessed portion 13 to seal the LED chip 14.

The case 10 includes a resin case 11 and a lead frame 12 which is exposed on the bottom surface 13a of the recessed portion 13. Electrodes of the LED chip 14 and the lead frame 12 are electrically connected by wires 15. In the case 10, the bottom surface 13a is formed of the resin case 11 and the lead frame 12, and the side surface 13b is formed of the resin case 11.

The resin case 11 is formed of, e.g., a thermoplastic resin such as polyphthalamide resin, LCP (liquid crystal polymer) or PCT (polycyclohexylene dimethylene terephthalate), etc., or a thermosetting resin such as silicone resin, modified silicone resin, epoxy resin or modified epoxy resin, etc., and is formed by injection molding. The resin case 11 may contain light-reflecting particles of titanium dioxide, etc., to improve light reflectance.

Preferably, the bottom surface 13a of the recessed portion 13 of the case 10 does not have a special shape including protrusion or recess and is flat. In this case, it is possible to use an existing mold to form the resin case 11 and the lead frame 12 and it is thus not necessary to prepare a special mold, which allows the manufacturing cost to be kept low.

Although the LED chip 14 in FIGS. 1 and 2A is shown as a face-up type LED chip which is connected to the lead frame 12 via the wires 15, it is not limited thereto. The LED chip 14 may be, e.g., a flip-chip type LED chip which is connected to the lead frame 12 via conductive bumps.

The entire lead frame 12 or a surface thereof is formed of, e.g., Ag, Cu or Al. Alternatively, for example, a substrate having a conductor pattern on a surface thereof may be used in place of the lead frame 12.

The highly-reflective sidewall 16 is formed of a resin material containing light-reflecting particles of titanium dioxide, etc. The resin material constituting the highly-reflective sidewall 16 is, e.g., a thermoplastic resin such as polyphthalamide resin, LCP or PTC, etc., or a thermosetting resin such as silicone resin, modified silicone resin, epoxy resin or modified epoxy resin, etc. A concentration of the light-reflecting particles contained in the highly-reflective sidewall 16 is higher than a concentration of the light-reflecting particles contained in the resin case 11 and light reflectance of the highly-reflective sidewall 16 is higher than that of the resin case 11, e.g., that of the side surfaces 13b of the recessed portion 13 of the case 10.

The highly-reflective sidewall 16 is formed by applying and curing a liquid resin containing light-reflecting particles. A surface of the highly-reflective sidewall 16 exposed in the recessed portion 13 is an outwardly convex surface, which is because of a property, such as viscosity, of the liquid resin before curing.

In addition, a height of the highly-reflective sidewall 16 is smaller than that of the case 10. Accordingly, a decrease in light emission amount caused by narrowing an opening area of the case 10 can be suppressed.

It is preferable that the highly-reflective sidewall 16 be formed in as much area around the LED chip 14 as possible in order to further improve light extraction efficiency. When a planar shape of the recessed portion 13 of the case 10 is, e.g., square as shown in FIG. 1, forming the highly-reflective sidewall 16 on two side surfaces 13b facing each other with the LED chip 14 interposed therebetween improves light extraction efficiency by 2.8% as compared to the case where the highly-reflective sidewall 16 is not formed at all, and forming the highly-reflective sidewall 16 on four side surfaces 13b improves light extraction efficiency by 8.4%.

The sealing member 17 is formed of, e.g., a resin material such as silicone-based resin or epoxy-based resin, etc., or glass. In addition, the sealing member 17 may contain phosphor particles. For example, when emission color of the LED chip 14 is blue and that of the phosphor contained in the sealing member 17 is yellow, emission color of the light-emitting device 1 is white.

Alternatively, the highly-reflective sidewall 16 may be formed so as to partially cover the wires 15, as shown in FIG. 2B.

An example of a method of manufacturing the light-emitting device 1 will be described below.

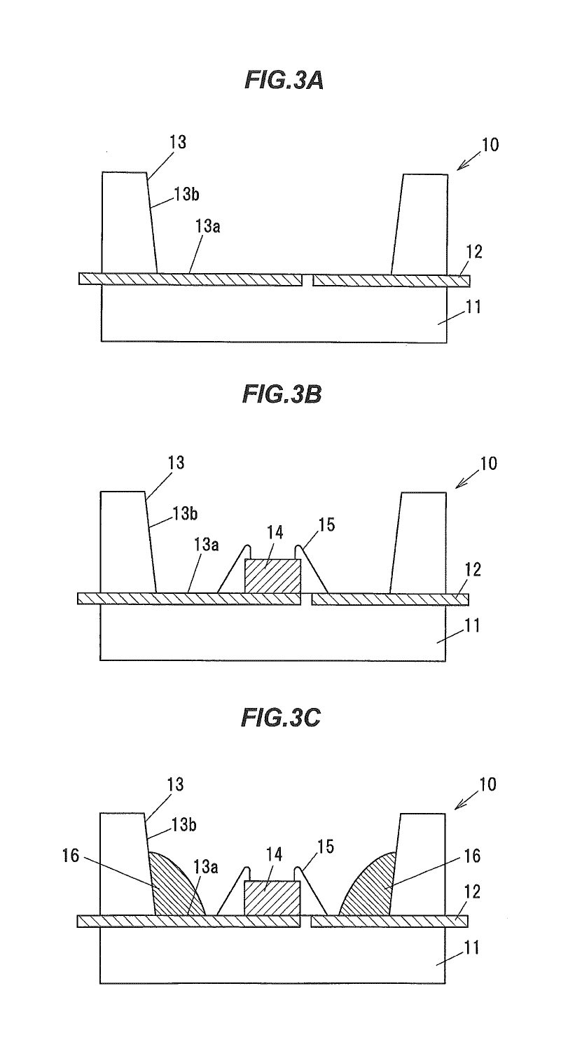

FIGS. 3A to 3C are vertical cross-sectional views showing a manufacturing process of the light-emitting device 1 in the first embodiment.

Firstly, as shown in FIG. 3A, the case 10 having the recessed portion 13 is prepared.

Next, as shown in FIG. 3B, the LED chip 14 is mounted on the bottom surface 13a of the recessed portion 13 of the case 10.

Next, as shown in FIG. 3C, a liquid resin is applied in contact with the side surfaces 13b and the bottom surface 13a of the recessed portion 13 and is cured by heating, etc., thereby forming the highly-reflective sidewall 16. The highly-reflective sidewall 16 is not in contact with the LED chip 14.

At this time, although the bottom surface 13a of the recessed portion 13 is flat, it is possible to prevent the liquid resin from flowing and coming into contact with the LED chip 14 by controlling viscosity, etc., of the liquid resin.

The liquid resin exhibits low wettability to the bottom surface 13a and the side surfaces 13b of the recessed portion 13 and has a relatively small contact angle. Therefore, a surface of the highly-reflective sidewall 16 formed by curing the liquid resin (a surface which is exposed in the recessed portion 13) is an outwardly convex surface.

In addition, since the highly-reflective sidewall 16 is formed after the LED chip 14 is mounted in the case 10, a space required for mounting the LED chip 14 or for connecting the wires 15 between the LED chip 14 and the highly-reflective sidewall 16 does not need to be provided unlike the case where the LED chip 14 is mounted after forming the highly-reflective sidewall 16, and it is therefore possible to downsize the case 10.

Alternatively, the highly-reflective sidewall 16 may be preliminarily molded outside the case 10 and then placed in the case 10. A method of molding the highly-reflective sidewall 16 in this case is a molding method with high dimensional accuracy, e.g., such as injection molding or a molding method in which a resin is potted in a mold by screen printing.

The LED chip 14 is sealed with the sealing member 17 after forming the highly-reflective sidewall 16, thereby obtaining the light-emitting device 1 shown in FIGS. 1 and 2A.

Effects of the First Embodiment

In the first embodiment, light emitted from the LED chip 14 is efficiently reflected by providing the highly-reflective sidewall 16 having a high light reflectance and it is thereby possible to improve light extraction efficiency of the light-emitting device 1.

In addition, flow of the liquid resin toward the LED chip 14 is suppressed by controlling viscosity, etc., of the liquid resin and it is thereby possible to prevent a decrease in light output of the LED chip 14 which is caused because the resin covers the LED chip 14.

Furthermore, since the flow of the liquid resin toward the LED chip 14 can be suppressed even though the bottom surface 13a of the recessed portion 13 is flat, it is not necessary to provide a protrusion or a recess on the resin case 11 and the lead frame 12 which constitute the case 10. Therefore, it is possible to use an existing mold to form the resin case 11 and the lead frame 12 and it is thereby possible to keep the manufacturing costs low.

In addition, providing the highly-reflective sidewall 16 allows light resistance of the light-emitting device 1 to be maintained, regardless of a material of the resin case 11. When, for example, an inclined angle of the side surface 13b of the recessed portion 13 is small, it is necessary to use a resin with high flowability in order to sufficiently spread the resin in a mold used for forming the resin case 11. However, in general, a resin with high flowability often has low light resistance, resulting in low light resistance of the resin case 11. Even in such a case, deterioration of the resin case 11 due to light can be suppressed by covering the exposed portion of the resin case 11 with the highly-reflective sidewall 16.

In addition, when a thermoplastic resin such as nylon or PCT is used as a material of the resin case 11, the thermoplastic resin left over in the molding of the resin case 11 can be collected, melted and reused as a material of another resin case 11. In this regard, discoloration of the thermoplastic resin occurs by repeating such reuse, which leads to change in color of the resin case 11 and resulting change in emission color of the light-emitting device 1. However, even in such a case, the change in emission color of the light-emitting device 1 due to the change in color of the resin case 11 can be suppressed by covering the exposed portion of the resin case 11 with the highly-reflective sidewall 16.

### Second Embodiment

The second embodiment is different from the first embodiment in the position of placing the highly-reflective sidewall. Note that, the explanation for the same configuration as the first embodiment will be omitted or simplified.

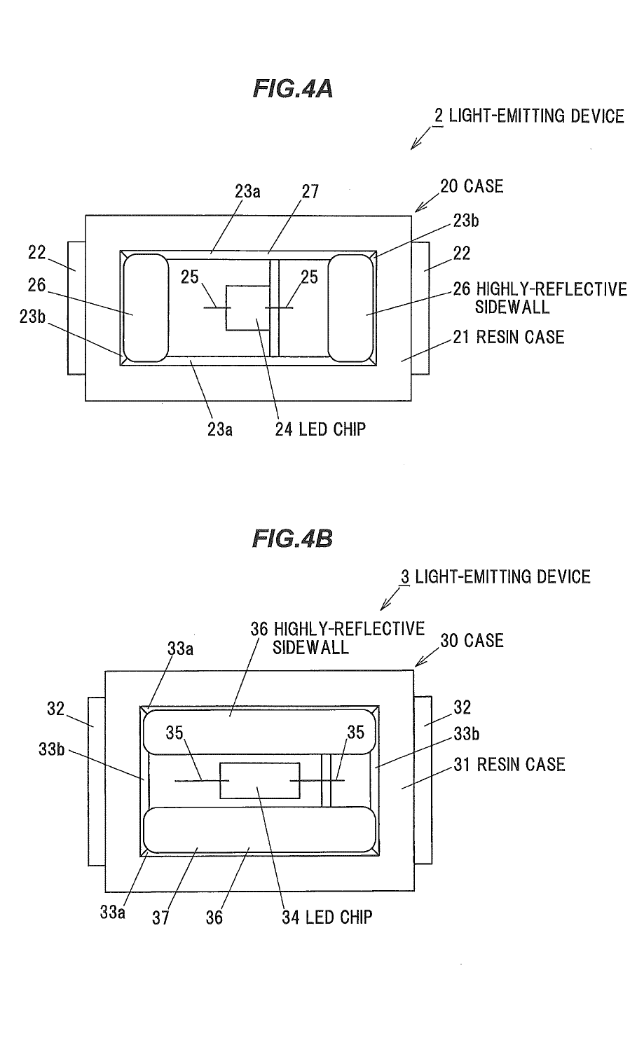

FIG. 4A is a top view showing a light-emitting device in the second embodiment.

A light-emitting device 2 has a case 20, an LED chip 24, highly-reflective sidewalls 26 and a sealing member 27. The case 20 includes a resin case 21 and a lead frame 22. The LED chip 24 is connected to the lead frame 22 via, e.g., wires 25. Note that, a planar shape of a recessed portion of the case 20 is rectangular, as shown in FIG. 4A.

The light-emitting device 2 has two side surfaces 23a facing each other with the LED chip 24 interposed therebetween and two side surfaces 23b also facing each other with the LED chip 24 interposed therebetween, and the highly-reflective sidewalls 26 are formed only on the side surfaces 23b. In the light-emitting device 2, a distance between the side surface 23a and the LED chip 24 is smaller than that between the side surface 23b and the LED chip 24. Therefore, if the highly-reflective sidewalls 26 are formed on the side surfaces 23a, the highly-reflective sidewalls 26 may come into contact with the LED chip 24 and block emission of light from the LED chip 24.

Therefore, in the light-emitting device 2, the highly-reflective sidewalls 26 are formed only on the side surfaces 23b and are not formed between the side surfaces 23a and the LED chip 24 so that light extraction efficiency of the light-emitting device 2 is improved while preventing the highly-reflective sidewalls 26 from coming into contact with LED chip 24.

FIG. 4B is a top view showing another light-emitting device in the second embodiment. A light-emitting device 3 has a case 30, an LED chip 34, a highly-reflective sidewall 36 and a sealing member 37. The case 30 includes a resin case 31 and a lead frame 32. The LED chip 34 is connected to the lead frame 32 via wires 35. Note that, a planar shape of a recessed portion of the case 30 is rectangular, as shown in FIG. 4B.

The light-emitting device 3 has two side surfaces 33a facing each other with the LED chip 34 interposed therebetween and two side surfaces 33b also facing each other with the LED chip 34 interposed therebetween, and the highly-reflective sidewalls 36 are formed only on the side surfaces 33a. In the light-emitting device 3, each wire 35 runs from the LED chip 34 toward a side surface 33b and a distance between the side surface 33b and the wire 35 is smaller than that between the side surface 33a and the wire 35. Therefore, if the highly-reflective sidewalls 36 are formed on the side surfaces 33b, a needle of a potting system may come into contact with and cut the wire 35.

Therefore, in the light-emitting device 3, the highly-reflective sidewalls 36 are formed only on the side surfaces 33a and are not formed between the side surfaces 33b and the LED chip 34 so that light extraction efficiency of the light-emitting device 3 is improved while preventing the wires 35 from being cut during the potting.

Note that, materials of the resin cases 21 and 31, the lead frames 22 and 32, the LED chips 24 and 34, the wires 25 and 35, the highly-reflective sidewalls 26 and 36 and the sealing members 27 and 37 are respectively the same as the materials of the resin case 11, the lead frame 12, the LED chip 14, the wire 15, the highly-reflective sidewall 16 and the sealing member 17 in the first embodiment.

### Third Embodiment

The third embodiment is different from the first embodiment in that the highly-reflective sidewall is placed during the molding of the resin case. Note that, the explanation for the same configuration as the first embodiment will be omitted or simplified.

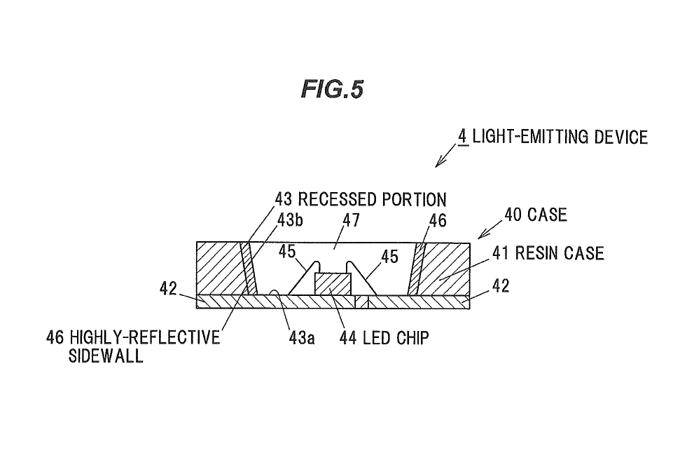

FIG. 5 is a vertical cross-sectional view showing a light-emitting device in the third embodiment. A light-emitting device 4 has a case 40 having a recessed portion 43, an LED chip 44 mounted on a bottom surface 43a of the recessed portion 43, a highly-reflective sidewall 46 placed so as to be in contact with side surfaces 43b and the bottom surface 43a of the recessed portion 43 and to be spaced from the LED chip 44, and a sealing member 47 potted in the recessed portion 43 to seal the LED chip 44.

The case 40 includes a resin case 41 and a lead frame 42. The LED chip 44 is connected to the lead frame 42 via wires 45.

Materials of the resin case 41, the lead frame 42, the LED chip 44, the wire 45 and the sealing member 47 are respectively the same as the materials of the resin case 11, the lead frame 12, the LED chip 14, the wire 15 and the sealing member 17 in the first embodiment.

The highly-reflective sidewall 46 is formed of a resin material such as acrylic resin or silicone resin.

The highly-reflective sidewall 46 has the same function as the highly-reflective sidewall 16 in the first embodiment. In addition, the highly-reflective sidewall 46 may be formed on all side surfaces 43b of the recessed portion 43 in the same manner as the first embodiment or may be formed on some of the side surfaces 43b in the same manner as the second embodiment.

An example of a method of manufacturing the light-emitting device 4 will be described below.

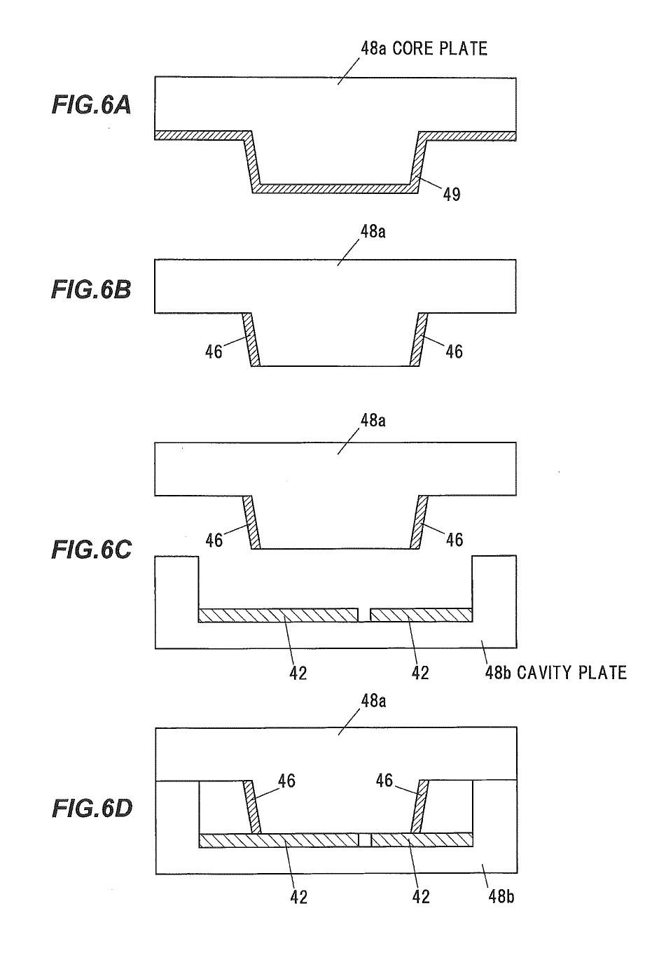

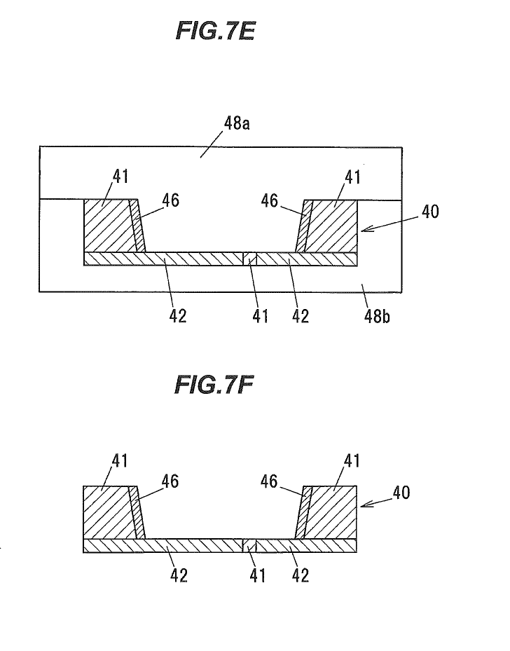

FIGS. 6A to 6D and FIGS. 7E and 7F are vertical cross-sectional views showing a manufacturing process of the light-emitting device in the third embodiment.

Firstly, as shown in FIG. 6A, a highly-reflective film 49 is formed so as to cover a surface of a core plate 48a which is a convex part of a mold used for injection molding. The highly-reflective film 49 is formed by spray coating, etc.

Next, as shown in FIG. 6B, the highly-reflective film 49 is shaped so that only a portion on side surfaces of the convex part of the core plate 48a is left, thereby forming the highly-reflective sidewall 46. The highly-reflective film 49 may be shaped by, e.g., removing a portion on a flat portion of the core plate 48a, or by using a mask such that the mask is formed on the flat portion of the core plate 48a before forming the highly-reflective film 49 and a portion of the highly-reflective film 49 on the mask is removed by lift-off.

Next, as shown in FIGS. 6C and 6D, the core plate 48a is fitted in a cavity plate 48b which is a concave part of the mold.

Next, as shown in FIG. 7E, the resin case 41 is formed by injecting a resin into a space (cavity) formed between the core plate 48a and the cavity plate 48b. The resin is injected through, e.g., a resin injection path (runner) provided on the core plate 48a. As a result, the case 40 is obtained.

Next, as shown in FIG. 7F, the core plate 48a is removed from the case 40 and the case 40 is then taken out of the cavity plate 48b. After the core plate 48a is removed from the case 40, the highly-reflective sidewall 46 remains on the case 40. In other words, the highly-reflective sidewall 46 is transferred from the core plate 48a to the case 40.

As described above, a dedicated special mold is not required to form the case 40 in which the highly-reflective sidewall 46 is provided on the side surfaces 43b of the recessed portion 43.

After that, the LED chip 44 is mounted in the case 40 and is then sealed with the sealing member 47, thereby obtaining the light-emitting device 4.

A modification of the method of manufacturing the light-emitting device 4 will be described below.

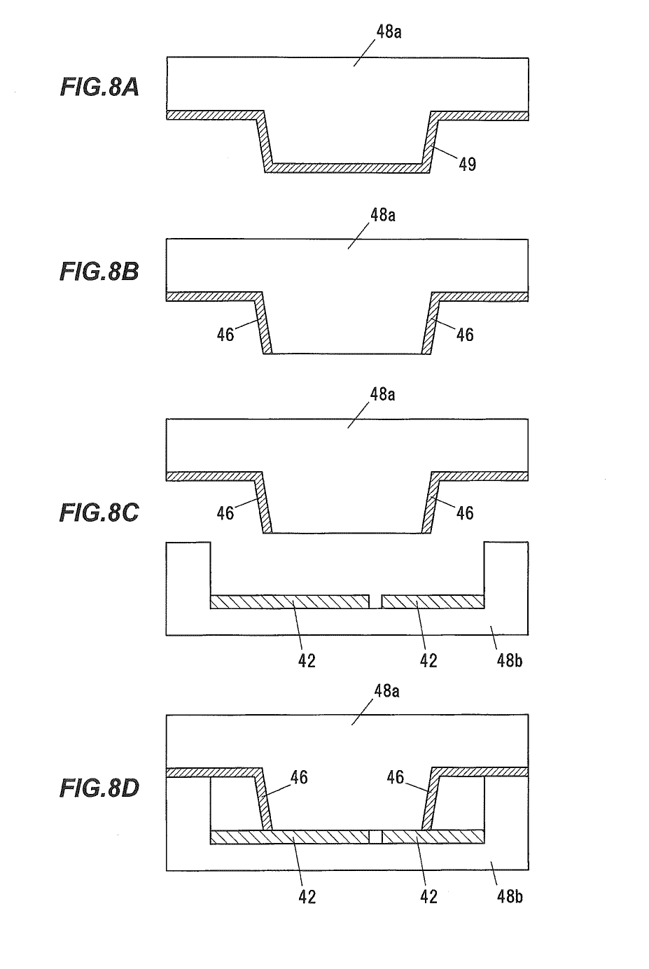

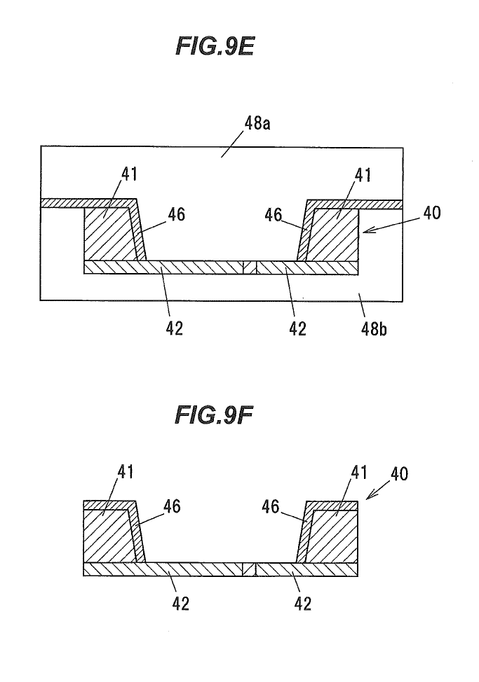

FIGS. 8A to 8D and FIGS. 9E and 9F are vertical cross-sectional views showing a manufacturing process of the light-emitting device in the third embodiment.

Firstly, as shown in FIG. 8A, the highly-reflective film 49 is formed so as to cover the surface of the core plate 48a.

Next, as shown in FIG. 8B, a portion of the highly-reflective film 49 on the flat portion of the convex part of the core plate 48a is removed, thereby forming the highly-reflective sidewall 46. Next, as shown in FIGS. 8C and 8D, the core plate 48a is fitted in the cavity plate 48b which is the concave part of the mold.

Next, as shown in FIG. 9E, the resin case 41 is formed by injecting a resin into a cavity formed between the core plate 48a and the cavity plate 48b. In this modification, the highly-reflective film 49 covers the side surfaces of the recessed portion of the resin case 41 and the upper surface of the resin case 41.

Next, as shown in FIG. 9F, the core plate 48a is removed from the case 40 and the case 40 is then taken out of the cavity plate 48b. After the core plate 48a is removed from the case 40, the highly-reflective sidewall 46 remains on the case 40. In other words, the highly-reflective sidewall 46 is transferred from the core plate 48a to the case 40. Here, a portion of the highly-reflective sidewall 46 which is not on the surface of the resin case 41 is removed.

After that, the LED chip 44 is mounted in the case 40 and is then sealed with the sealing member 47, thereby obtaining the light-emitting device 4.

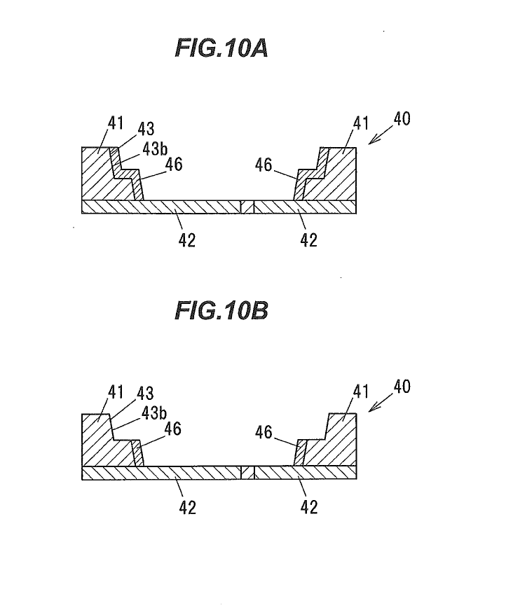

FIGS. 10A and 10B are vertical cross-sectional views showing a modification of the case 40. In the case 40 shown in FIGS. 10A and 10B, the side surfaces 43b of the recessed portion 43 of the resin case 41 have a stepped-shape. It is possible to form the case 40 having such a shape by the same processes as those shown in FIGS. 6A to 9F.

The present invention is not intended to be limited to the above-mentioned embodiments, and the various kinds of modifications can be implemented without departing from the gist of the invention.

In addition, the invention according to claims is not to be limited to the above-mentioned embodiments. Further, please note that all combinations of the features described in the embodiments are not necessary to solve the problem of the invention.

What is claimed is:

1. A method of manufacturing a light-emitting device, comprising:
mounting an LED chip on a bottom surface of a recessed portion of a case; and
after mounting the LED chip, forming a highly-reflective sidewall so as to be in contact with side surfaces and the bottom surface of the recessed portion and to be spaced from the LED chip,
wherein the highly-reflective sidewall comprises a higher light reflectance than the side surfaces of the recessed position of the case and an outwardly convex surface as a surface exposed in the recessed portion.

2. The method according to claim 1, wherein a height of the highly-reflective sidewall is smaller than that of the case.

3. The method according to claim 1, wherein the bottom surface of the recessed portion is flat.

4. The method according to claim 1, wherein the side surfaces of the recessed portion comprise two first side surfaces and two second side surfaces respectively facing each other with the LED chip interposed therebetween,
wherein a distance between the first side surface and the LED chip is smaller than that between the second side surface and the LED chip, and
wherein the highly-reflective sidewall is formed in a region other than between the first side surface and the LED chip.

5. The method according to claim 1, wherein a power-supply wire is connected to the LED chip,
wherein the side surfaces of the recessed portion comprise two first side surfaces and two second side surfaces respectively facing each other with the LED chip interposed therebetween,
wherein a distance between the second side surface and the wire is smaller than that between the first side surface and the wire, and
wherein the highly-reflective sidewall is formed in a region other than between the second side surface and the LED chip.

6. The method according to claim 1, wherein the highly-reflective sidewall is molded outside the case and is then placed so as to be in contact with the side surfaces and the bottom surface of the recessed portion and to be spaced from the LED chip.

7. The method according to claim 1, wherein the case is formed reusing a thermoplastic resin that is collected after molding other molded parts.

8. A method of manufacturing a light-emitting device, comprising:
forming a highly-reflective sidewall on a surface of a core plate of an injection mold;
forming a case including a resin case that is formed by injecting a resin into a space between the core plate having the highly-reflective sidewall formed thereon and a cavity plate of the injection mold; and
mounting an LED chip on a bottom surface of a recessed portion of the case,
wherein the highly-reflective sidewall is transferred from the core plate to the resin case so as to be provided on side surfaces of the recessed portion of the case.
